(19) United States
(12) Patent Application Publication
(10) Pub. No.: US 2009/0278192 A1
(43) Pub. Date: Nov. 12, 2009

(54) SEMICONDUCTOR DEVICE

(75) Inventors: Yong-Suk CHOI, Hwaseong-si (KR); Jeong-Uk HAN, Suwon-si (KR); Yong-Tae KIM, Yongin-si (KR); Seung-Jin YANG, Seoul (KR); Hyok-Ki KWON, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/433,971

(22) Filed: May 1, 2009

(30) Foreign Application Priority Data
May 6, 2008 (KR) 10-2008-0041859

(51) Int. Cl. H01L 29/792

(52) U.S. Cl. 257/324; 257/E29.309

(57) ABSTRACT

A semiconductor device includes a tunnel insulation layer pattern, a charge trapping layer pattern, a blocking layer pattern and a gate structure. The tunnel insulation layer pattern is formed on a substrate. The charge trapping layer pattern is formed on the tunnel insulation layer pattern. The blocking layer pattern is formed on the substrate and extends up onto and covers the charge trapping layer pattern. The gate surrounds an upper portion of the charge trapping layer pattern so as to face towards and upper surface and opposite side surfaces of the charge trapping layer pattern.

### BACKGROUND OF THE INVENTION

1. Field of the Invention

The present invention relates to a semiconductor device and to a method of manufacturing the semiconductor device. More particularly, the present invention relates to a non-volatile memory device having a charge trapping layer, such as a local silicon-oxide-nitride-oxide-silicon (SONOS) device, and to a method of manufacturing such a non-volatile memory device.

2. Description of the Related Art

A flash memory device may be classified as either a floating gate type of flash memory device or a charge trap type of flash memory device. As the names imply, a floating gate type of flash memory device uses a floating gate to form a memory cell, whereas a charge trap type of flash memory device uses a charge trapping layer to form a memory cell. One example of a charge trap type of flash memory device is a silicon-oxide-nitride-oxide-silicon (SONOS) type of non-volatile memory device. In a SONOS type of non-volatile memory device, a silicon nitride layer, for example, is used as the charge trapping layer.

In a SONOS type of non-volatile memory device, the charge trapping layer may be formed under a certain portion of a control gate for minimizing power consumption during programming and erasing operations, and for enhancing programming and erasing operation efficiency. In such a case, i.e., when only portions of a control gate and a charge trapping layer of a SONOS type of non-volatile memory device overlap each other, the SONOS type of non-volatile memory device may be referred to as a local SONOS type of non-volatile memory device.

However, it is difficult to form the control gate in alignment with the charge trapping layer when manufacturing a local SONOS type of non-volatile memory device, especially when the cell of the device is relatively small. Accordingly, the control gate and the charge trapping layer are often misaligned in a local SONOS type of non-volatile memory device. A misalignment of the control gate and the charge trapping layer causes the cell to have electrical characteristics which vary across the cell.

FIG. 1 is a cross-sectional view of a conventional local SONOS type of non-volatile memory device.

Referring to FIG. 1, the conventional local SONOS type of non-volatile memory device includes a substrate 10, a first silicon oxide layer 15 on the substrate 10, a silicon nitride layer 20 on portion of the first silicon oxide layer 15, a second silicon oxide layer 25 on the first silicon oxide layer 15 and the silicon nitride layer 20, and a gate 35 on the second silicon oxide layer 25. The first silicon oxide layer 15, the silicon nitride layer 20 and the second silicon oxide layer 25 constitute an ONO (oxide-nitride-oxide) layer 30.

A first photolithography process is used for forming the local silicon nitride layer 20 and a second photolithography process is used for forming the gate 35. However, a misalignment error can occur between the first and second photolithography processes such that the lengths 41 and 42 over which the gate 35 spans segments of the silicon nitride layer 20, respectively, are not the same. It follows that the lengths 43 and 44 of those portions of the silicon nitride layer 20 spanned by the gate 35, respectively, will also be different. Such a misalignment causes differences amongst the cells in both the effective length of the control gate 35 and in the effective length of the local silicon nitride layer 20 (i.e., differences amongst the cells' capacity for charge trapping). Accordingly, the operating characteristics of the cells are undesirably non-uniform.

### SUMMARY OF THE INVENTION

One object of the present invention is to provide a method of manufacturing a semiconductor device which ensures that a gate is properly aligned with a charge trapping layer.

Another object of the present invention is to provide a method of manufacturing a semiconductor device which ensures that a gate is properly aligned with a blocking layer.

Another object of the present invention is to provide a semiconductor device having uniform cells.

Similarly, another object of the present invention is to provide a method of manufacturing a semiconductor device having uniform cells.

Yet another object of the present invention is to provide a semiconductor device having a cell that provides a high level of capacitance.

According to one aspect of the present invention, there is provided a method of manufacturing a semiconductor device using a sacrificial layer pattern to align a first gate with a charge trapping layer. A preliminary tunnel insulation layer, a preliminary charge trapping layer and a preliminary sacrificial layer are sequentially formed on a substrate. A charge trapping layer and a sacrificial layer are formed by etching the preliminary charge trapping layer and the preliminary sacrificial layer. A portion of the sacrificial layer is removed to form a sacrificial layer pattern which exposes a portion of the charge trapping layer. A blocking layer is formed on the substrate so as to extend up onto the charge trapping layer. At least one first gate is formed on the blocking layer. The first gate has a first gate portion that extends over the charge trapping layer and a second gate portion that extends from the first gate portion off of from over the charge trapping layer. The sacrificial layer pattern and the remaining portion of the charge trapping layer disposed under the sacrificial layer pattern are then removed. The sacrificial layer pattern may be removed by first wet etching the sacrificial layer pattern until an upper surface of the sacrificial layer pattern is substantially at the same level as the upper surface of the portion of the blocking layer which extends over the charge trapping layer, and then remaining the remainder of the sacrificial layer pattern using a dry etching process.

According to another aspect of the invention, opposite side portions of the sacrificial layer may be removed to form the sacrificial layer pattern. The side portions are substantially equal to each other in terms of their thicknesses so that symmetrical cells can be formed. In particular, a pair of the first gates may be formed symmetrically with respect to the sacrificial layer.

According to yet another aspect of the invention, the blocking layer is formed by forming a thermal oxidation layer on the substrate and the charge trapping layer, and then forming a middle temperature oxide layer on the thermal oxidation layer.

A second gate may also be formed on the substrate. In this case, the second gate is disposed adjacent to the charge trapping layer and the first gate. The first gate and the second gate may also be electrically connected to each other. For example, the first and the second gates may be electrically connected to each other by a metal silicide layer. Alternatively, a wire may be formed on the first and the second gates and in contact with the first and the second gates so as to electrically connect the first and second gates.

In addition, an insulation layer may be formed on sidewalls of the charge trapping layer, the blocking layer and the first gate before the second gate is formed. The insulation layer may also have a substantially uniform thickness along the sidewalls of the charge trapping layer, the blocking layer and the first gate. The insulation layer may also extend along the substrate between adjacent cells and along the sidewalls of structures of the cells each constituted by segments of the tunnel insulation layer, charge trapping layer, and blocking layer and the first gate.

According to another aspect of the present invention, there is provided a method of manufacturing a semiconductor device in which a tunnel insulation layer pattern is formed on a substrate, a charge trapping layer pattern is formed on the tunnel insulation layer pattern, a blocking layer pattern is formed over the charge trapping layer pattern on the substrate, and a gate structure is formed on the blocking layer pattern such that the gate structure surrounds an upper portion of the charge trapping layer pattern. That is, the gate structure has portions facing towards an upper surface and opposite side surfaces of the charge trapping layer pattern.

According to another aspect of the present invention, there is provided a semiconductor device including a tunnel insulation layer pattern, a charge trapping layer pattern, a blocking layer pattern, and a gate structure aligned with the charge trapping layer pattern. The tunnel insulation layer pattern is disposed on a substrate. The tunnel insulation layer pattern is disposed on the tunnel insulation layer pattern. The blocking layer pattern is disposed on the substrate over the charge trapping layer pattern. The gate structure is disposed on the blocking layer pattern. The gate structure surrounds an upper portion of the charge trapping layer pattern so as to have portions facing towards an upper surface and opposite side surfaces of the charge trapping layer pattern

The gate structure may include a first gate extending over an upper portion of the charge trapping layer pattern and a second gate. The second gate faces the sidewall of the first gate. An insulation layer may be interposed between the first gate and the second gate. Also, the first gate and the second gate are electrically connected to each other. The semiconductor device may also include a metal silicide layer on the first gate and the second gate and, for example, the metal silicide layer may electrically connect the first and second gates. Alternatively, the semiconductor device may include a wire contacting the first gate and the second gate so as to electrically connect the first and second gates.

According to another aspect of the present invention, there is provided a semiconductor device having symmetrical cells disposed on a substrate. Each of the cells includes a tunnel insulation layer pattern on the substrate, a charge trapping layer pattern on the tunnel insulation layer pattern, a blocking layer pattern on the charge trapping layer pattern, a first gate is on the blocking layer pattern, a second gate, and an insulation layer. The first gate extends from the substrate to an upper portion and a first sidewall of the charge trapping layer pattern. The first gate, the blocking layer pattern, the charge trapping layer pattern, and the tunnel layer pattern have sidewalls that are substantially flush with one another. The insulation layer extends contiguously along the sidewalls of the tunnel insulation layer pattern, the charge trapping layer pattern, the blocking layer pattern, and the first gate so as to be interposed between the first and second gates. The second gate, however, is electrically connected to the first gate.

### BRIEF DESCRIPTION OF THE DRAWINGS

These and other objects, features and advantages of the present invention will be more clearly understood from the following detailed description taken in conjunction with the accompanying drawings. In the drawings:

FIG. 1 is a cross-sectional view of a conventional local silicon-oxide-nitride-oxide-silicon (SONOS) type of non-volatile memory device;

FIGS. 2 to 12 are each a cross-sectional view of a substrate, and together illustrate a method of manufacturing a local SONOS type of non-volatile memory device in accordance with the present invention; and

FIG. 13 is a cross-sectional view of a local SONOS type of non-volatile memory device in accordance with the present invention.

### DETAILED DESCRIPTION OF THE EMBODIMENTS

The present invention will be described more fully hereinafter with reference to the accompanying drawings. Those numerals which are the same in different drawings designate like elements. Also, in the drawings, the sizes and relative sizes of layers and regions may be exaggerated for clarity.

Furthermore, when an element or layer is referred to as being disposed “on,” another element or layer, such a description includes the case in which the element or layer is disposed directly on the other element or layer as well as the case in which another element(s) or layer(s) is/are present therebetween. Likewise, when an element is referred to as being “connected to” or “coupled to” another element, such a description includes the case in which the element is directly connected or coupled to the other element as well as the case in which another element(s) is/are coupled or connected therebetween.

Terms, such as “beneath,” “below,” “lower,” “above,” “upper” and the like, may be used herein to describe the spacial relationship between one element (or feature) and another as illustrated in the figures. However, the element(s) or feature(s) may assume other spacial relationships in actual use depending on the orientation of the device with which they are integarated. Thus, it will be understood that the terms used in the specification, such as “beneath,” “below,” “lower,” “above,” “upper” and the like are relative terms used for ease of description only and thus, are not limiting in their own right.

Also, in the specification, the term “pattern” is sometimes used interchangeably to designate both a pattern of identical features formed from a layer of material as well as an individual feature of the pattern, i.e., a feature of a size and shaped that is repeated. In some cases, for the sake of better clarity, such an individual feature will not be referred to as a pattern but as a segment of the pattern. In any case, the meaning of the term “pattern” as used throughout the specification and claims will be clear given the context in which the term is being used.

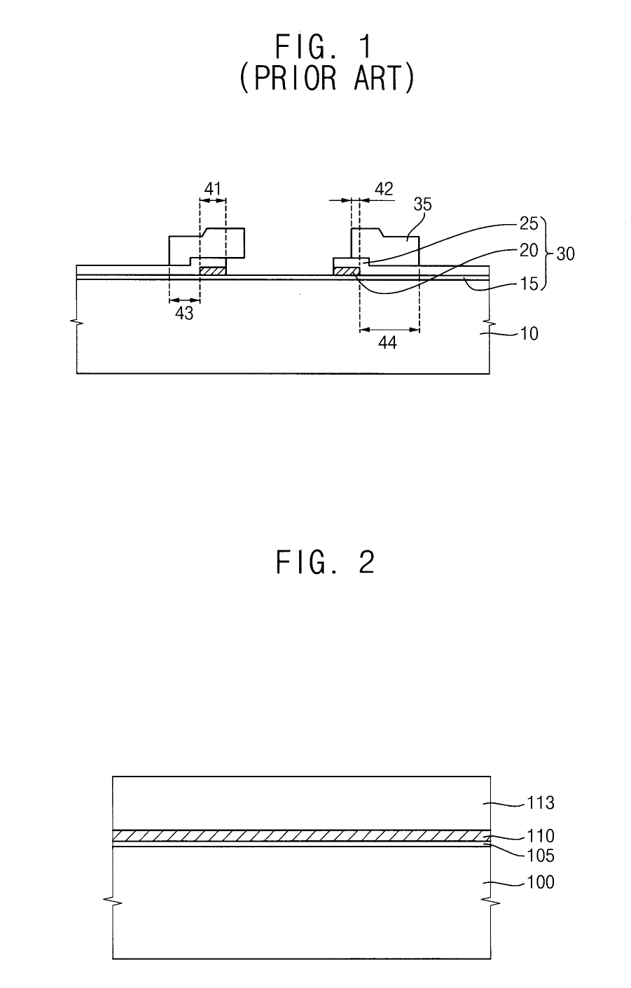

The present invention will be described in detail hereinafter with reference to FIGS. 2-13.

Referring first to FIG. 2, a preliminary first tunnel insulation layer 105 is formed on a substrate 100. The substrate 100 may be a metal oxide single crystalline substrate, a silicon substrate, a germanium substrate, a silicon-germanium substrate, a silicon-on-insulator (SOI) substrate, or a germanium-on-insulator (GOI) substrate, or may comprise a substratum on which an epitaxial film is formed.

The preliminary first tunnel insulation layer 105 may comprise an oxide or an oxynitride. For example, the preliminary first tunnel insulation layer 105 may be a silicon oxide layer or an oxynitride layer. Also, the preliminary first tunnel insulation layer 105 may be formed by a chemical vapor deposition (CVD) process, a low-pressure chemical vapor deposition (LPCVD) process, or a plasma-enhanced chemical vapor deposition (PECVD) process.

A preliminary charge trapping layer 110 is formed on the preliminary first tunnel insulation layer 105. The preliminary charge trapping layer 110 is formed using a material having charge trapping sites such as silicon nitride, boron nitride, aluminum oxide, aluminum oxynitride, or oxide having a high dielectric constant. In the present embodiment, the preliminary charge trapping layer 110 is a layer of silicon nitride. The preliminary charge trapping layer 110 may be formed using a thermal oxidation process, a CVD process, an LPCVD process, a PECVD process, or an ALD.

A preliminary sacrificial layer 113 is formed on the preliminary charge trapping layer 110. The thickness of the preliminary sacrificial layer 113 is designed to establish the proper thickness and length of a first gate (120 in FIG. 6) during a subsequent process to be described later on. In this respect, the preliminary sacrificial layer 113 is substantially thicker than the preliminary charge trapping layer 110 because the thickness of the preliminary sacrificial layer 113 relates to the thickness of the first gate 120.

The preliminary sacrificial layer 113 is of material having an etch selectivity (wet or dry) with respect to the preliminary charge trapping layer 110. For example, the preliminary sacrificial layer 113 is of an oxide when the preliminary charge trapping layer 110 is a layer of silicon oxynitride. Also, the preliminary sacrificial layer 113 may be of material having an etch selectivity with respect to the preliminary first tunnel insulation layer 105. The preliminary sacrificial layer 113 may be formed by a CVD process, an LPCVD process, a PECVD process, or an ALD process.

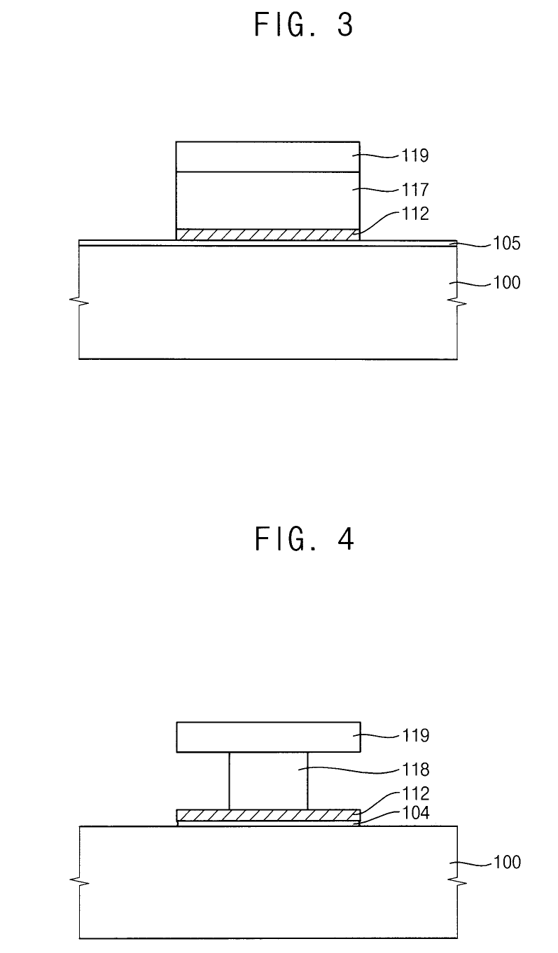

Referring to FIG. 3, a mask 119 is formed on the preliminary sacrificial layer 113. The mask 119 is of material having an etch selectivity with respect to the preliminary sacrificial layer 113 and the preliminary charge trapping layer 110. For example, the mask 119 may be a photoresist pattern.

The preliminary sacrificial layer 113 and the preliminary charge trapping layer 110 are patterned using the mask 119 as an etching mask to form a charge trapping layer 112 and a sacrificial layer 117 on the preliminary tunnel layer 105. Charges can thus be stored in charge trapping sites of the charge trapping layer 112.

In the present embodiment, the charge trapping layer 112 and the sacrificial layer 117 are formed by a dry etching process. In this respect, the preliminary sacrificial layer 113 and the preliminary charge trapping layer 110 may be patterned by a reactive ion etching (RIE) process, an ion beam etching process, a sputtering etching process, or a radio frequency process. As a result, the charge trapping layer 112 and the sacrificial layer 117 have substantially the same size (surface area).

Referring to FIG. 4, side portions of the sacrificial layer 117 are removed to form a sacrificial layer pattern 118 between the charge trapping layer 112 and the mask 119. In addition, that portion of the preliminary first tunnel insulation layer 105 which lies under the charge trapping layer 112 is etched away to form a first tunnel insulation layer 104 on the substrate 100.

In the present embodiment, the sacrificial layer 117 is etched in a direction parallel to the plane of the substrate 100 to form the sacrificial layer pattern 118 whose width is substantially less than that of the charge trapping layer 112. In this respect, the sacrificial layer 117 may be wet etched or a dry etched. A spray type of wet etching method, in which wet etchant is sprayed onto the sides of the sacrificial layer 117 in directions parallel to the plane of the substrate, may be used to ensure that both sides of the sacrificial layer 117 are etched equally.

Also, at this time, the mask 119 and the charge trapping layer 112 are not etched because the sacrificial layer 117 has an etch selectivity with respect to the mask 119 and the charge trapping layer 112. On the other hand, the first tunnel insulation layer 105 may be etched while the side portions of the sacrificial layer 117 are being etched when the sacrificial layer 117 and the first tunnel insulation layer 105 are both oxide layers. That is, the first tunnel insulation layer pattern 104 may be formed between the substrate 100 and the charge trapping layer 112 while the sacrificial layer pattern 118 is being formed. At this time, though, edge portions of the first tunnel insulation layer pattern 104 may be damaged because of the difference in thickness between the first tunnel insulation layer 105 and the sacrificial layer 117. Specifically, a recess or a dent may be formed in each edge portion of the first tunnel insulation layer pattern 104 under the charge trapping layer 112.

In any case, the thicknesses of the side portions of the sacrificial layer 117 that are removed are substantially the same because both sides of the sacrificial layer 117 are etched away under substantially the same conditions. Therefore, the widths of the recesses in the sides of the resulting structure (FIG. 4), in which the sacrificial layer pattern 118 has been formed, are equal to each other. The widths of the recesses may be controlled by controlling the time over which the etching process is carried out. That is, side portions of the sacrificial layer 117 of predetermined thicknesses may be removed to form the sacrificial layer pattern 118. The thicknesses (amounts) of the sacrificial layer 117 that are etched away establish, the length of a charge trapping layer pattern (130 in FIG. 8) and the first gate 120, which are formed during subsequent processes to be described later on. Specifically, the removal of the side portions of the sacrificial layer 117 exposes side portions of the charge trapping layer 112 on the first tunnel insulation layer 104, and the length of the exposed portion of the charge trapping layer 112 corresponds to the length of the charge trapping layer pattern 130.

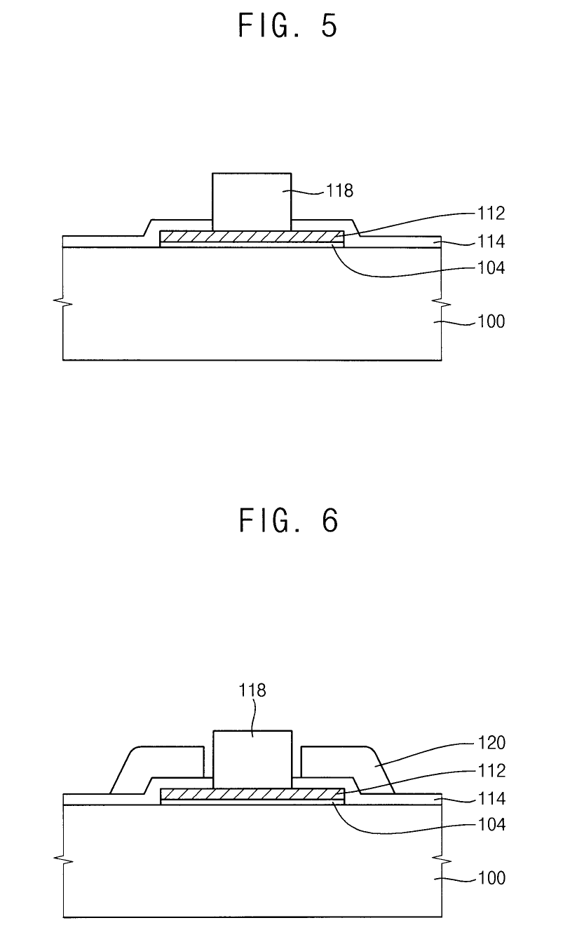

Referring to FIG. 5, the mask 119 is removed from the sacrificial layer 118. The mask 119 may be removed by an ashing process and/or a stripping process when the mask 119 is a layer of photoresist. Then, a blocking layer 114 is formed on the substrate 100 over the exposed portion of the charge trapping layer 112 and the first tunnel insulation layer 104. In this respect, the blocking layer 114 may be formed over the entire structure except for the sacrificial layer pattern 118. That is, the blocking layer 114 may be formed around a lower portion of the sacrificial layer pattern 118 on the substrate 100.

The blocking layer 114 may be formed of an oxide such as silicon oxide. The blocking layer 114 also has an etch selectivity with respect to the sacrificial layer pattern 118. For example, even when both the blocking layer 114 and the sacrificial layer pattern 118 are layers of silicon oxide, respectively, the blocking layer 114 may be provided with an etch selectivity with respect to the sacrificial layer pattern 118 by forming the silicon oxide of the blocking layer 114 so as to be substantially more dense or less porous than the silicon oxide of the sacrificial layer pattern 118.

The blocking layer 114 may be formed on the substrate 100 by a thermal oxidation process. For example, a thermal oxide layer is grown from the substrate 100 by a thermal oxidation process, and then a middle temperature oxide layer is formed. The aforementioned damage to the first tunnel insulation layer 104 created while the sacrificial layer pattern 118 is being etched may be cured or compensated for in this way. That is, a recess or dent in an edge of the first tunnel insulation layer 104 may be cured or compensated for when the blocking layer 114 is formed by a thermal oxidation process.

In the present embodiment, the blocking layer 114 is formed by depositing silicon oxide on the substrate 100, the charge trapping layer 112 and the first tunnel insulation layer 104 by a CVD process, a PECVD process, or an a LPCVD process. Thus, the blocking layer 114 is formed uniformly over the substrate 100 and the charge trapping layer 112. Furthermore, the blocking layer 114 covers a sidewall and of the sacrificial layer pattern 118 and, although not illustrated, the blocking layer 114 may also cover an upper portion of the sacrificial layer pattern 118. A portion of the blocking layer 114 that covers the sidewall of the sacrificial layer pattern 118 (or the sidewall and the upper portion of the sacrificial layer pattern 118) is removed when the sacrificial layer pattern 118 is removed as will be described in more detail later on.

In any case, the blocking layer 114 electrically insulates the first gate 120 from the substrate 100. Thus, a segment of the blocking layer along which the blocking layer 114 makes contact with the substrate may serve as a gate dielectric layer (a dielectric between the first gate 120 and the substrate 100).

Next, a first conductive layer (not illustrated) is formed on the substrate 100 over the blocking layer 114 and the sacrificial layer pattern 118. Referring to FIG. 6, the first conductive layer is etched by, for example, an etch back process to form the first gate 120 on the blocking layer 114. The first conductive layer may be a layer of polysilicon doped with impurities, a metal layer or a layer of a metal compound. For example, the first conductive layer is formed using tungsten (W), tungsten silicide (WN), titanium (Ti), titanium silicide (TiSi), tantalum (Ta), tantalum silicide (TaSi), and/or cobalt silicide (CoSi). The first conductive layer may be formed by a CVD process, a PECVD process, an ALD process, a sputtering process, or a pulsed laser deposition (PLD) process. When the first gate 120 is formed on a cell region of the substrate 100, a gate of a transistor forming a logic circuit may be simultaneously formed on a peripheral region of the substrate.

The first gate 120 may be formed to substantially the same height as or below the level of the sacrificial layer pattern 118. Also, portion of the first gate 120 extends along an upper portion of the blocking layer 114 and hence, over the charge trapping layer 112. Furthermore, the first conductive layer may be etched so that the portion of the first gate 120 which extends along the blocking layer 114 is spaced apart from the sidewall of the sacrificial layer pattern 118. Alternatively, the blocking layer 114 may be formed so as to extend along the sidewalls of the sacrificial layer pattern 118. In this case, the blocking layer 114 is disposed between the sacrificial layer pattern 118 and the first gate 120 such that the first gate 120 is spaced from the sidewall of the sacrificial layer pattern 118.

The extent to which the first gate 120 and the blocking layer 114 overlap, and the height of the first gate 120 may be provided by controlling the conditions under which the first conductive layer is etched. In this regard, the extent to which the first gate 120 and the blocking layer 114 overlap is a dimension designed for according to desired characteristics of the local SONOS type of flash memory device that is being fabricated. In particular, on the extent to which the first gate 120 and the blocking layer 114 overlap is formed to be great enough to prevent charges may from migrating unexpectedly between the first impurity region (101 in FIG. 10) and the second impurity region (102 in FIG. 10) of the local SONOS type of flash memory device.

Although reference has been made above to the forming of a single gate 120, as can be seen from FIG. 6 a pair of the first gates 120 are symmetrically formed on the blocking layer 114 with respect to the sacrificial pattern layer 118. Accordingly, the misalignment that can occur in the prior art as described with reference to FIG. 1 is prevented. Also, the first gates 120 overlap the charge trapping layer 112 on both sides of the sacrificial pattern layer 118 by substantially the same amounts. Accordingly, a structure including the first tunnel insulation layer 104, the charge trapping layer 112, the blocking layer pattern 114 and the first gates 120 is formed symmetrically on the substrate 100 with respect to the sacrificial layer pattern 118. As a result, cells can be formed uniformly on the substrate 100 and more particularly, cells having uniform electrical characteristics can be formed, as will become even more apparent from the following.

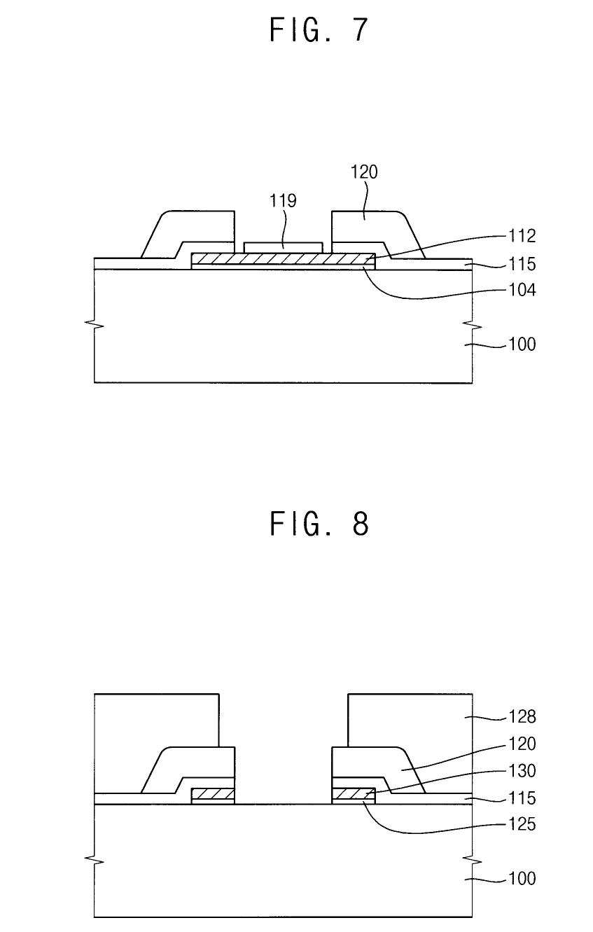

Referring to FIGS. 7 and 8, the sacrificial layer pattern 118 is removed from the blocking layer 114, and the blocking layer 114, the charge trapping layer 112 and the first tunnel insulation layer 104 are patterned to form a tunnel insulation layer pattern 125, a charge trapping layer pattern 130 and blocking layer pattern 115 on the substrate 100. The sacrificial layer pattern 118 may be removed from the blocking layer 114 by a wet etching process or a dry etching process. Also, at this time, any portions of the blocking layer 114 which extend to or along the sidewalls, and along the upper portion of the sacrificial layer pattern 118 are removed to form the blocking layer pattern 115.

In the present embodiment, though, the blocking layer 114 is formed as terminating at the sidewalls of the sacrificial layer pattern 118, and the sacrificial layer pattern 118 is of material having an etch selectivity with respect to the materials of the blocking layer 114 and the first gate 120. For example, the sacrificial layer pattern 118 and the blocking layer 114 are each formed of silicon oxide, but the silicon oxide of sacrificial layer pattern 118 is formed so as to have a density substantially less than or a porosity substantially greater than that of the silicon oxide of the blocking layer 114. Accordingly, the sacrificial layer pattern 118 is selectively removed and the blocking layer 114 remains on the substrate 100.

As illustrated in FIG. 8, the blocking layer pattern 115, the charge trapping layer pattern 130, and the tunnel insulation layer pattern 125 are formed using a mask 128, such as a photoresist pattern. More specifically, the mask 128 is formed over respective portions of the first gates 120, the blocking layer 114, the charge trapping layer 112 and the tunnel insulation layer 104 after the sacrificial layer pattern 118 has been removed. Then the charge trapping layer 112 and the tunnel insulation layer 104 are etched using the first gates 120 and the mask 128 as an etching mask to form the charge trapping layer pattern 130 and the tunnel insulation layer pattern 125. Accordingly, the process of forming the tunnel insulation layer pattern 125, the charge trapping layer pattern 130 and the blocking layer pattern 115 is highly reliable. The mask 128 may then be removed from the first gates 120 by an ashing process or a stripping process.

Note, although generally speaking a wet etching process has a greater etching rate than a dry etching process, the blocking layer 114 could be damaged by a wet etching process if such a wet etching process were used to remove the sacrificial layer pattern 118. Thus, in one embodiment according to the present invention, the sacrificial layer pattern 118 is wet etched down to the level of the blocking layer 114. Then, the remaining portion 119 (FIG. 7) of the sacrificial layer pattern is removed from the charge trapping layer 112 by a dry etching process. For example, the remaining portion 119 of the sacrificial layer pattern is removed by an RIE process, an ion beam etching process, a sputtering etching process, or a radio frequency etching process. Accordingly, when the sacrificial layer pattern 118 is removed not only rapidly but also without damaging the blocking layer 114.

Finally, as a result of the process, two cells are formed symmetrically on the substrate 100, each of the cells including respective segments of the tunnel insulation layer pattern 125, the charge trapping layer pattern 130, and the blocking layer pattern 115 and a respective one of the first gates 120.

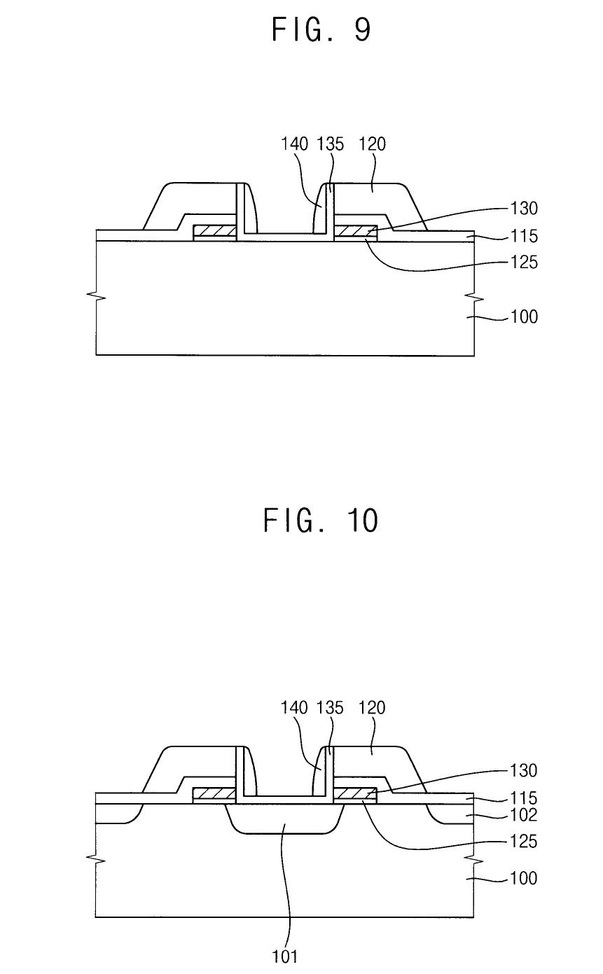

Referring to FIG. 9, an insulation layer 135 is formed on an exposed portion of the substrate 100 and along sidewalls of the structure formed by the first gates 120, the blocking layer pattern 115, the charge trapping layer pattern 130 and the tunnel insulation layer pattern 125. The insulation layer 135 may comprise a middle temperature oxide layer. Preferably, the insulation layer 135 has a uniform thickness. A space between the cells is not filled by the insulation layer 135.

Second gates 140 are formed on the insulation layer 135. The insulation layer 135 will thus electrically insulate the second gates 140 and the charge trapping layer pattern 130. The second gates 140 may be formed of polysilicon doped with impurities, a metal or a metal compound. For example, the second gates 140 are formed using tungsten (W), tungsten silicide (WN), titanium (Ti), titanium silicide (TiSi), tantalum (Ta), tantalum silicide (TaSi), and/or cobalt silicide (CoSi). Also, the second gates 140 may be formed of the same or different materials from the first gates 120.

In the present embodiment, a second conductive layer (not illustrated) is formed on the insulation layer 135. The second conductive layer is patterned by an etch-back process, for example, to form the second gates 140. At this time, the insulation layer 135 protects the sidewalls of the first gates 120. Also, the portion of the insulation layer 135 which extends along the surface of the substrate 100 may serve as an etch-stop layer to protect the substrate. Accordingly, the substrate 100 is not damaged when the second conductive layer is patterned to form the second gates 140.

As best shown in FIG. 9, the second gates 140 are formed on portions of the insulation layer 135, respectively, which cover sidewalls of the structure includes the first gates 120, the blocking layer pattern 115 and the charge trapping layer pattern 130. Furthermore, each first gate 120 is formed adjacent to an upper surface of a segment of the charge trapping layer pattern 130. Therefore, an upper portion of each segment of the charge trapping layer pattern 130 is surrounded by a first gate 120 and a second gate 140, and insulation is interposed between the charge trapping layer pattern 130 and the first and second gates 120 and 140. Accordingly, the first and second gates 120 and 140 present a relatively large area facing the charge trapping layer pattern 130, and the structure formed by the charge trapping layer pattern 130, the first and second gates 120 and 140 and the insulation therebetween has a relatively high capacitance.

Referring to FIG. 10, a first impurity region 101 is formed at a first portion of the substrate 100 under the insulation layer 135. That is, the first impurity region 101 is formed at the substrate 100 between the first gates 120. The cells are symmetrically disposed with respect to the first impurity region 101. A second impurity region 102 is formed at a second portion of the substrate 100 under the blocking layer pattern 115. The first impurity region 101 and the second impurity region 102 may be formed simultaneously or sequentially. Furthermore, the first impurity region 101 may become a source region of the device which is being fabricated, and the second impurity region 102 may become a drain region of the device.

In the present embodiment, a photoresist pattern is used as an ion implantation mask for forming the first impurity region 101 and the second impurity region 102. The concentration at which ions are implanted into the substrate 100 to form the first impurity region 101 may be substantially greater than of the concentration at which ions are implanted into the substrate 100 to form the second impurity region 102. Also, the first impurity region 101 may be formed using an ion beam whose energy level is substantially higher than that used to form the second impurity region 102.

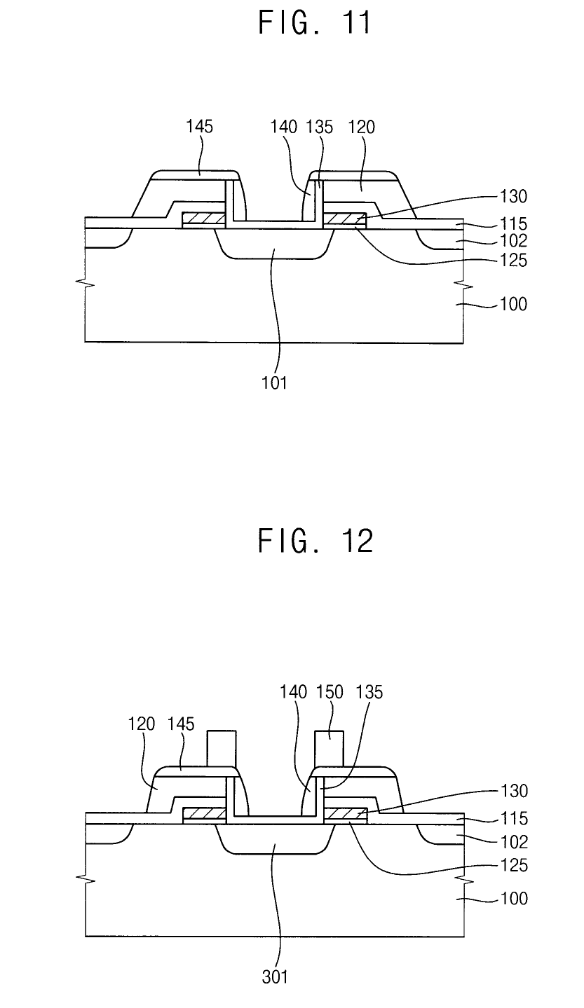

Referring to FIG. 11, a metal silicide layer 145 is optionally formed on the first and second gates 120 and 140. It should be noted that the first and second impurity regions 101 and 102 may be formed in the substrate 100 after the metal silicide layer 145 is formed on the first and second gates 120 and 140.

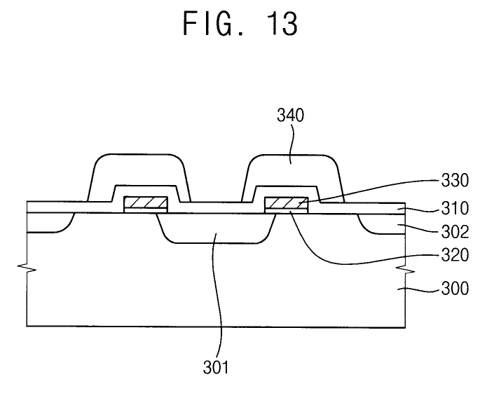

The metal silicide layer 145 may be formed using tungsten silicide (WSi), cobalt silicide (CoSi), and/or titanium silicide (TiSi). More specifically, a metal layer (not illustrated) of tungsten, cobalt or titanium, for example, is formed on the first and second gates 120 and 140. The metal layer is then be subjected to a rapid thermal annealing (RTA) process to form the metal silicide layer 145. As a result, the metal layer is reacted with the first and second gates 120 and 140 to form the metal silicide layer 145. The metal silicide layer 145 may also be formed on the first and second impurity regions 101 and 102. Also, the first gate 120 and the second gate 140 may be electrically conductively connected by the metal silicide layer 145. More specifically, as the metal silicide layer 145 is formed on the first and second gates 120 and 140, a portion of the metal silicide layer 145 grows over the upper portion of the insulation layer 135 to electrically connect the first gate 120 to the second gate 140. Alternatively, a wire (150 in FIG. 12) is formed to electrically connect the first gate 120 and the second gate 140.

In this case, with reference to FIG. 12, the wire 150 is formed on the metal silicide layer 145 in contact with the first and second gates 120 and 140. The wire 150 may be formed of a metal or may be a carbon nanotube. More specifically, an insulation interlayer (not illustrated) is formed over the cells on the substrate, and then the insulation interlayer is etched to form an opening exposing the metal silicide layer 145. The opening is filled with the conductive material to form the wire 150. In the case in which a metal silicide layer is not employed, the first and the second gates 120 and 140 are exposed through the opening, and the wire 150 is formed in contact with the first and the second gates 120 and 140. Thus, the first and the second gates 120 and 140 are integrated by the wire 150 into a single gate structure.

In any case, a gate structure including respective ones of the first and second gates 120 and 140 is formed on the substrate to enclose (a segment of) the charge trapping layer pattern 130. That is, the gate structure has the shape of an inverted “U” set atop the charge trapping layer pattern 130. Therefore, as mentioned above, the gate structure presents a relatively large area facing the charge trapping layer pattern 130, i.e., a high capacitance is provided.

As is clear from the description above, each cell of an embodiment of a SONOS type flash memory device will include, in accordance with the present invention, a tunnel insulation layer pattern 125, a charge trapping layer pattern 130 disposed on the tunnel insulation layer pattern 125, a blocking layer pattern 115 disposed on the charge trapping layer pattern 130 and extending along a surface of the substrate 100, a first gate 120 extending from the blocking layer pattern 115 to up over the charge trapping layer pattern 130, an insulation layer 135 extending over sidewalls of the first gate 120, the blocking layer pattern 115, the charge trapping layer pattern 130 and the tunnel insulation layer pattern 125, and a second gate 140 disposed on the insulation layer 135.

Furthermore, the substrate 100 has a first impurity region 101 and a second impurity region 102. The tunnel insulation layer pattern 125 is formed in a region of the substrate 100 located between the first impurity region 101 and the second impurity region 102. The tunnel insulation layer pattern 125 may also overlap portion of the first impurity region 101.

As is also clear from the description above, according to the present invention, a pair of such cells may be symmetrically disposed on the substrate 100 with respect to a plane that extends perpendicular to the substrate and bisects a gap between the second gates 140 of the cells. The first impurity region 101 spans the cells so as to be disposed to one side of each of the cells, and the second impurity region 102 is disposed to the other side of each of the cells.

FIG. 13 illustrates another embodiment of a local SONOS type of non-volatile memory device in accordance with the present invention.

Referring to FIG. 13, the local SONOS type of non-volatile memory device includes a substrate 300, a tunnel insulation layer pattern 320, a charge trapping layer pattern 330, a blocking layer 310, and gates 340. The substrate 300 has a first impurity region 301 spanning the gates 340 so as to be disposed to one side of each of the gates 340, and a second impurity region 302 disposed to the other side of each of the gates 340. The elements of this local SONOS type of non-volatile memory device are substantially the same as or similar to those of the local SONOS type of non-volatile memory device shown in FIG. 12 with some exceptions as follows.

The blocking layer 310 is a contiguous layer of material that spans the cells. Each gate 340 is formed on a portion of the blocking layer pattern 310 which lies above the charge trapping layer pattern 330. Each gate 340 also surrounds an upper portion of the charge trapping layer pattern 330. For example, each gate 340 may have the shape of an inverted “U” set over the charge trapping layer pattern 330. Also, a first portion of each gate 340 adjacent to the first impurity region 301 has a thickness, as measured in direction parallel to the plane of the substrate, that is substantially less than that of a second portion of the gate 340 adjacent to a second impurity region 302. The cells, each including a tunnel insulation layer pattern 320, a charge trapping layer pattern 330 and a gate 340, are symmetrical with respect to the first impurity region 301.

In a method of manufacturing the local SONOS type of non-volatile memory device shown in FIG. 13, according to the present invention, the tunnel insulation layer pattern 320 is formed on the substrate 300. The charge trapping layer pattern 330 is formed on the tunnel insulation layer pattern 320. The blocking layer 310 is formed over the charge trapping layer pattern 330. The gates 340 are then formed on the blocking layer 310.

According to the present invention as described above, in d a method of manufacturing a semiconductor device, a charge trapping layer and a gate of each of a pair of cells are formed using a self-alignment technique. Thus, the area over which the charge trapping layer and the gate overlap may be uniform in amongst the cells. Also, the area over which the gate and blocking layer pattern overlap may also be uniform in amongst the cells. Accordingly, the electrical characteristics of the cells are uniform. Thus, the device is highly reliable. Also, the gate structure faces the charge trapping layer over a relatively large area, so that the device provides a high capacitance.

The foregoing is illustrative of the present invention and is not to be construed as limiting thereof. Although the present invention has been described in connection with the preferred embodiments thereof, those skilled in the art will readily appreciate that many modifications of the disclosed embodiments are possible without materially departing from the true spirit and scope of the present invention as defined in the claims.

1-13. (canceled)

14. A semiconductor device comprising:
a tunnel insulation layer pattern on a substrate;
a charge trapping layer pattern on the tunnel insulation layer pattern;
a blocking layer pattern on the substrate, the blocking layer pattern covering the charge trapping layer pattern; and
a gate structure on the blocking layer pattern, the gate structure surrounding an upper portion of the charge trapping layer pattern so as to face an upper surface and opposite side surfaces of the charge trapping layer pattern.

15. The semiconductor device of claim 14, wherein the gate structure includes a first gate extending having a first gate portion extending over an upper portion of the charge trapping layer pattern and a second gate portion extending from the first gate portion off of from over the charge trapping layer pattern and on the substrate, and a second gate on the substrate, the second gate facing a side wall of the first gate.

16. The semiconductor device of claim 15, further comprising an insulation layer interposed between the first gate and the second gate.

17. The semiconductor device of claim 15, wherein the first gate and the second gate are electrically connected to each other.

18. The semiconductor device of claim 17, further comprising a metal silicide layer on the first gate and the second gate.

19. The semiconductor device of claim 17, further comprising a wire contacting the first gate and the second gate.

20. A semiconductor device comprising:
a substrate; and
a pair of symmetrical cells on the substrate, each of the cells including a tunnel insulation layer pattern,
a charge trapping layer pattern on the tunnel insulation layer pattern,
a blocking layer pattern on the charge trapping layer pattern and the substrate;
a first gate on the blocking layer pattern, the first gate having a first gate portion extending over the charge trapping layer and a second gate portion which extends off of from over the charge trapping layer from the first gate portion so as to lie over the substrate,
the first gate portion, the blocking layer pattern, the charge trapping layer pattern, and the tunnel layer pattern having sidewalls that are substantially flush with one another,
an insulation layer extending contiguously along the sidewalls of the tunnel insulation layer pattern, the charge trapping layer pattern, the blocking layer pattern, and the first gate, and
a second gate on the insulation layer pattern, the second gate being electrically connected to the first gate.
